(19) United States
(12) Patent Application Publication
(10) Pub. No.: US 2019/0172850 A1
(43) Pub. Date: Jun. 6, 2019

(54) OLED ARRAY SUBSTRATE, METHOD FOR MANUFACTURING THE SAME AND OLED DISPLAY DEVICE

(71) Applicant: BOE TECHNOLOGY GROUP CO., LTD., Beijing (CN)

(72) Inventor: Lizhong WANG, Beijing (CN)

(21) Appl. No.: 16/323,678

(22) PCT Filed: May 14, 2018
(86) PCT No.: PCT/CN2018/086661

§ 371 Date: Feb. 6, 2019

(30) Foreign Application Priority Data
May 25, 2017 (CN) 201710380212.0

(51) Int. Cl. H01L 27/12

(52) U.S. Cl. CPC H01L 27/1237; H01L 27/3244; H01L 27/1259

(57) ABSTRACT

An OLED array substrate, a method for manufacturing the same and an OLED display device are provided. The OLED array substrate includes a switching transistor for controlling a pixel to display and a driving transistor for driving the pixel to display. The switching transistor includes an active layer, a gate, and a first insulation layer provided between the active layer and the gate, and the driving transistor includes an active layer, a gate, and a second insulation layer provided between the active layer and the gate of the driving transistor. The first insulation layer has a dielectric constant greater than that of the second insulation layer.

### CROSS-REFERENCE TO RELATED APPLICATIONS

This is a National Phase Application filed under 35 U.S.C. 371 as a national stage of PCT/CN2018/086661, filed May 14, 2018, an application claiming the benefit of Chinese Application No. 201710380212.0, filed on May 25, 2017, the contents of which are incorporated herein in their entirety by reference.

### TECHNICAL FIELD

The present disclosure relates to the field of mobile apparatus technology, and in particular, relates to an OLED array substrate, a method for manufacturing the same, and an OLED display device.

### BACKGROUND

With the development of display technology, an organic light-emitting diode (OLED) display technology has become a hot topic of research due to an OLED's advantages of self-luminous, wide viewing angle, high contrast, low power consumption, high response speed, and the like.

### SUMMARY

Embodiments of the present disclosure provide an OLED array substrate, a method for manufacturing the same and an OLED display device.

Embodiments of the present disclosure provide an OLED array substrate, which includes a switching transistor for controlling a pixel to display and a driving transistor for driving the pixel to display, wherein the switching transistor includes an active layer, a gate, and a first insulation layer provided between the active layer and the gate, the driving transistor includes an active layer, a gate, and a second insulation layer provided between the active layer and the gate of the driving transistor, and the first insulation layer has a dielectric constant greater than that of the second insulation layer.

Optionally, the first insulation layer is made of silicon nitride, and the second insulation layer is made of silicon dioxide.

Optionally, the first insulation layer has a thickness ranging from 50 nm to 150 nm, and the second insulation layer has a thickness ranging from 120 nm to 200 nm.

Optionally, the first insulation layer includes a bottom sub-layer and a top sub-layer which are stacked on each other, the bottom sub-layer is in contact with the active layer of the switching transistor, and the top sub-layer is in contact with the gate of the switching transistor;
the bottom sub-layer is made of silicon dioxide, and the top sub-layer is made of silicon nitride; and
the second insulation layer is made of silicon dioxide.

Optionally, the bottom sub-layer has a thickness ranging from 30 nm to 50 nm, and the top sub-layer has a thickness ranging from 50 nm to 150 nm; and
the second insulation layer has a thickness ranging from 120 nm to 200 nm.

Optionally, each of the active layer of the switching transistor and the active layer of the driving transistor is made of low temperature poly-silicon.

Optionally, both the switching transistor and the driving transistor are one of top-gate transistors and bottom-gate transistors.

Embodiments of the present disclosure provide an OLED display device, which includes the OLED array substrate according to any one of the above embodiments of the present disclosure.

Embodiments of the present disclosure provide a method for manufacturing an OLED array substrate, the OLED array substrate being the OLED array substrate according to any one of the above embodiments of the present disclosure, and the method including steps of forming the switching transistor and forming the driving transistor, wherein the step of forming the switching transistor includes forming the first insulation layer between the active layer and the gate of the switching transistor, and the step of forming the driving transistor includes forming the second insulation layer between the active layer and the gate of the driving transistor, such that the first insulation layer has a dielectric constant greater than that of the second insulation layer.

Optionally, the active layer of the switching transistor and the active layer of the driving transistor are made of a same material by one process, and the gate of the switching transistor and the gate of the driving transistor are made of a same material by one process.

### BRIEF DESCRIPTION OF THE DRAWINGS

FIG. 1 is a schematic partial sectional view showing a structure of an OLED array substrate according to an embodiment of the present disclosure;

FIG. 2 is a schematic partial sectional view showing a structure at step S101 of a method for manufacturing the OLED array substrate shown in FIG. 1;

FIG. 3 is a schematic partial sectional view showing a structure at step S102 of a method for manufacturing the OLED array substrate shown in FIG. 1; and

FIG. 4 is a schematic partial sectional view showing a structure at step S103 of a method for manufacturing the OLED array substrate shown in FIG. 1.

### DETAILED DESCRIPTION

To enable one of ordinary skill in the art to better understand the technical solutions of the present disclosure, an OLED array substrate, a method for manufacturing the same, and an OLED display device provided by the present disclosure will be further described in detail below with reference to the accompanying drawings and specific embodiments.

The inventor of the present disclosure has found that, in the field of flat panel display technology, since a low temperature poly-silicon thin film transistor (LTPS TFT) has the advantages of high response speed, high aperture ratio, high brightness, and the like, the LTPS technology is increasingly favored in the market. Further, the LTPS technology may be applied to flexible displays and organic light-emitting diode displays referred to as next-generation displays.

An OLED array substrate is generally provided with a switching transistor (e.g., a switching TFT) for controlling a pixel to display and a driving transistor (e.g., a driving TFT) for driving the pixel to display thereon. To increase a switching speed of the switching transistor, the switching transistor is generally expected to have a small subthreshold swing (SS). However, to better display the different gray levels of an OLED display, the driving transistor is required to have a large subthreshold swing (SS); otherwise, a too fast voltage change will cause the gray levels to be displayed incompletely, thereby deteriorating the display effect of the OLED display.

Therefore, it has become a technical problem to be solved urgently to decrease the subsreshold swing of the switching transistor of the OLED array substrate while increasing the subsreshold swing of the driving transistor of the OLED array substrate.

An embodiment of the present disclosure provides an OLED array substrate. As shown in FIG. 1, the OLED array substrate includes a switching transistor 1 for controlling a pixel to display and a driving transistor 2 for driving the pixel to display.

The switching transistor 1 includes an active layer 11, a gate 12, and a first insulation layer 13 provided between the active layer 11 and the gate 12, and the driving transistor 2 includes an active layer 21, a gate 22, and a second insulation layer 23 provided between the active layer 21 and the gate 23 of the driving transistor 2. The first insulation layer 13 has a dielectric constant greater than that of the second insulation layer 23.

Since the first insulation layer 13 has a dielectric constant greater than that of the second insulation layer 23, a capacitance between the gate 12 and the active layer 11 of the switching transistor 1 is increased relative to that of the driving transistor 2, which causes a subthreshold swing of the switching transistor 1 to be decreased relative to that of the driving transistor 2, thereby increasing a switching speed of the switching transistor 1. Further, a capacitance between the gate 22 and the active layer 21 of the driving transistor 2 is decreased relative to that of the switching transistor 1, which delays a voltage change of the driving transistor 2, such that a subthreshold swing of the driving transistor 2 is increased relative to that of the switching transistor 1, the incomplete display of gray levels of an OLED display device due to a too fast voltage change of the driving transistor 2 is avoided, and the display effect of the gray levels of the OLED device is improved.

In the present embodiment, optionally, the first insulation layer 13 may be made of silicon nitride, and the second insulation layer 23 may be made of silicon dioxide.

As an example, the first insulation layer 13 may have a thickness ranging from 50 nm to 150 nm, and the second insulation layer 23 may have a thickness ranging from 120 nm to 200 nm. The first insulation layer 13, made of the above material and having the above thickness, enables a capacitance between the gate 12 and the active layer 11 of the switching transistor 1 to be increased relative to that of the driving transistor 2, which causes a subthreshold swing of the switching transistor 1 to be decreased relative to that of the driving transistor 2, thereby increasing a switching speed of the switching transistor 1. Further, the second insulation layer 23, made of the above material and having the above thickness, enables a capacitance between the gate 22 and the active layer 21 of the driving transistor 2 to be decreased relative to that of the switching transistor 1, which delays a voltage change of the driving transistor 2, such that a subthreshold swing of the driving transistor 2 is increased relative to that of the switching transistor 1, the incomplete display of gray levels of an OLED display device due to a too fast voltage change of the driving transistor 2 is avoided, and the display effect of the gray levels of the OLED device is improved.

It should be noted that, the first insulation layer 13 and the second insulation layer 23 may also be made of other insulating materials, and the thicknesses thereof may be set according to the insulating materials employed, as long as it is ensured that a dielectric constant of the first insulation layer 13 is greater than a dielectric constant of the second insulation layer 23, a switching speed of the switching transistor 1 is increased, a voltage change of the driving transistor 2 is delayed, and the gray levels of the OLED display device are completely displayed.

In the present embodiment, both the active layer 11 of the switching transistor 1 and the active layer 21 of the driving transistor 2 may be made of low temperature poly-silicon. For the switching transistor 1 and the driving transistor 2 whose active layers are made of low temperature poly-silicon material, the above relationship between the dielectric constants of the first insulation layer 13 and the second insulation layer 23 will result in more significant technical effects.

It should be noted that, the active layer 11 of the switching transistor 1 and the active layer 21 of the driving transistor 2 may also be made of amorphous silicon or an oxide semiconductor material.

In this embodiment, both the switching transistor 1 and the driving transistor 2 may be top-gate transistors. Alternatively, the switching transistor and the driving transistor may also be bottom-gate transistors. That is, the above relationship between the dielectric constants of the first insulation layer 13 and the second insulation layer 23 are also applicable to bottom-gate transistors of the OLED array substrate.

Further, in the present embodiment, the OLED array substrate may further include a glass substrate 3 and a buffer layer 4 provided on the glass substrate 3. The active layer 11 of the switching transistor 1 and the active layer 21 of the driving transistor 2 are provided on the buffer layer 4. The gate 12 of the switching transistor 1 is provided on the first insulation layer 13, and the gate 22 of the driving transistor 2 is provided on the second insulation layer 23. A source 14 and a drain 15 of the switching transistor 1 are provided above the gate 12 of the switching transistor 1, and a third insulation layer 5 is provided between the source 14/the drain 15 and the gate 12. A source 24 and a drain 25 of the driving transistor 2 are provided above the gate 22 of the driving transistor 2, and the third insulation layer 5 is provided between the source 24/the drain 25 and the gate 22.

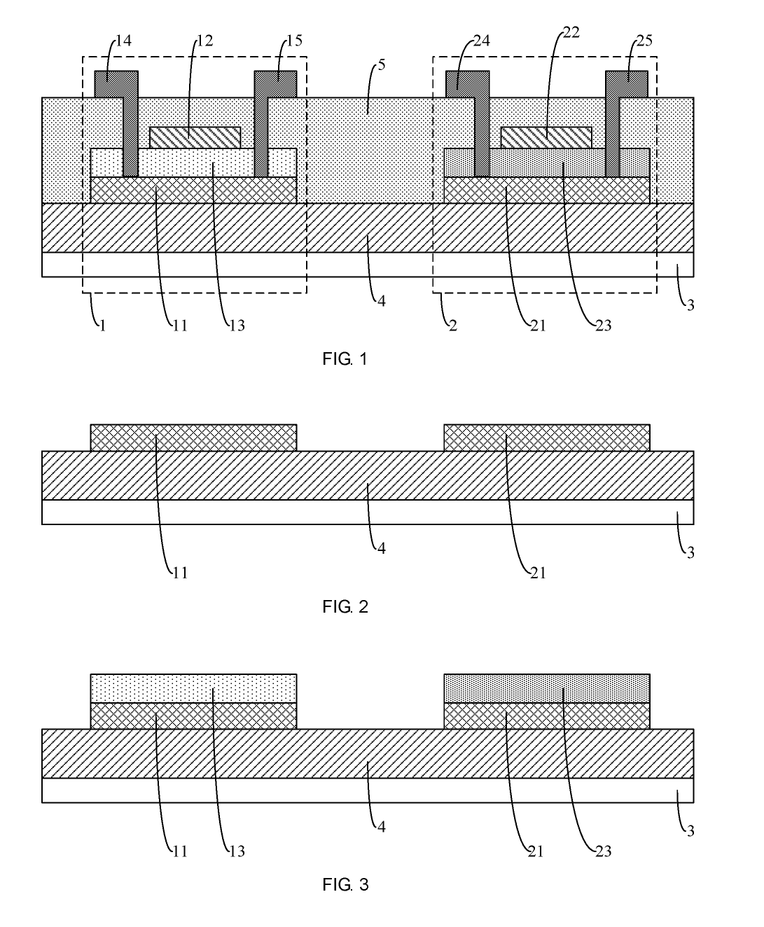

In addition to the above OLED array substrate, the present embodiment further provides a method for manufacturing the array substrate. As shown in FIGS. 2 to 4, the method may include forming the switching transistor 1 and the driving transistor 2. The forming of the switching transistor 1 may include forming the first insulation layer 13 between the active layer 11 and the gate 12 of the switching transistor 1, and the forming of the driving transistor 2 may include forming the second insulation layer 23 between the active layer 21 and the gate 22 of the driving transistor 2, such that an dielectric constant of the first insulation layer 13 is greater than a dielectric constant of the second insulation layer 23.

As an example, the forming of the switching transistor 1 and the driving transistor 2 may include the following steps S101 to S103.

At step S101, on the glass substrate 3, a silicon nitride (SiN) layer having a thickness ranging from 50 nm to 150 nm and a silicon dioxide (SiO₂) layer having a thickness ranging from 100 nm to 500 nm are deposited as the buffer layer 4, by a plasma enhanced chemical vapor deposition (PECVD) method. Next, an amorphous silicon (a-Si) layer having a thickness ranging from 30 nm to 100 nm is deposited, and then the amorphous silicon layer is transformed into a polysilicon (p-Si) layer by a laser quenching (e.g., excimer laser annealing, simply referred to as ELA) process. Finally, the active layer 11 of switching transistor 1 and the active layer 21 of the driving transistor 2 are formed by one patterning process (as shown in FIG. 2).

At step S102, a silicon dioxide (SiO₂) layer having a thickness ranging from 120 nm to 200 nm is deposited by a plasma enhanced chemical vapor deposition (PECVD) method, then a patterning process is performed on the silicon dioxide layer to form the second insulation layer 23 of the driving transistor 2. Next, a silicon nitride (SiN) layer having a thickness ranging from 50 nm to 150 nm is deposited by a plasma enhanced chemical vapor deposition (PECVD) method, and then a patterning process is performed on the silicon nitride layer to from the first insulation layer 13 of the switching transistor 1 (as shown in FIG. 3).

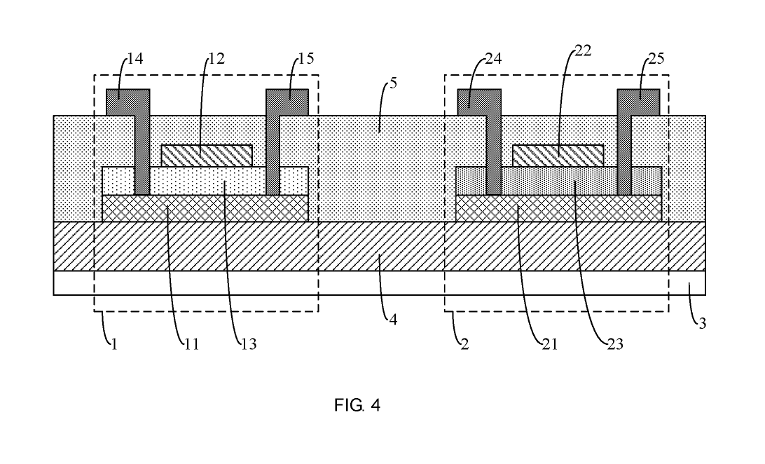

At step S103, other layers of the switching transistor 1 and the driving transistor 2 are formed by a patterning process. That is, the gate 12 of the switching transistor 1 and the gate 22 of the driving transistor 2 are simultaneously formed on the glass substrate 3 on which the step S102 has been finished. Then, a third insulation layer 5 is formed on the gates. Finally, on the third insulation layer 5, the source 14 and the drain 15 of the switching transistor 1, the source 24 and the drain 25 of the driving transistor 2, and additional layers (such as a pixel layer and the like) of the OLED array substrate may be formed (as shown in FIG. 4).

As an example, the source 14 and the drain 15 of the switching transistor 1 and the source 24 and the drain 25 of the driving transistor 2 are formed of a same material by one patterning process, and a specific process thereof may be referred to the foregoing description and will be omitted here. Further, the gate 12 of the switching transistor 1 and the gate 22 of the driving transistor 2 are formed of a same material by one patterning process, and a specific process thereof may be referred to the foregoing description and will be omitted here. Methods for forming the third insulation layer 5 and additional layers of the OLED array substrate may be conventional patterning processes, and thus detailed description thereof are omitted herein.

An embodiment of the present disclosure provides another OLED array substrate. The OLED array substrate according to the present embodiment differs from that according to the foregoing embodiments in that, the first insulation layer includes a bottom sub-layer and a top sub-layer which are stacked on each other, the bottom sub-layer is in contact with the corresponding active layer, the top sub-layer is in contact with the corresponding gate, the bottom sub-layer is made of silicon dioxide, the top sub-layer is made of silicon nitride, and the second insulation layer is made of silicon dioxide.

With such a configuration, the bottom sub-layer made of silicon dioxide is in contact with the corresponding active layer, which can reduce interface defects of the corresponding active layer and improve the an interface effect of the corresponding active layer, thereby making the switching control performance of the switching transistor more stable.

Correspondingly, in the present embodiment, the bottom sub-layer may have a thickness ranging from 30 nm to 50 nm, the top sub-layer may have a thickness ranging from 50 nm to 150 nm, and the second insulation layer may have a thickness ranging from 120 nm to 200 nm.

The first insulation layer, made of the above material and having the above thickness, enables a capacitance between the gate and the active layer of the switching transistor to be increased relative to that of the driving transistor, which causes a subthreshold swing of the switching transistor to be decreased relative to that of the driving transistor, thereby increasing a switching speed of the switching transistor. Further, the second insulation layer, made of the above material and having the above thickness, enables a capacitance between the gate and the active layer of the driving transistor to be decreased relative to that of the switching transistor, which delays a voltage change of the driving transistor, such that a subthreshold swing of the driving transistor is increased relative to that of the switching transistor, the incomplete display of gray levels of an OLED display device due to a too fast voltage change of the driving transistor is avoided, and the display effect of the gray levels of the OLED device is improved.

Other structures of the OLED array substrate according to the present embodiment and a method for manufacturing the same may be the same as those according to the foregoing embodiments, and detailed description thereof are omitted here.

Advantageous technical effects of the foregoing embodiments are as follows. In the OLED array substrate according to any one of the foregoing embodiments, since the first insulation layer has a dielectric constant greater than that of the second insulation layer, a capacitance between the gate and the active layer of the switching transistor is increased relative to that of the driving transistor, which causes a subthreshold swing of the switching transistor to be decreased relative to that of the driving transistor, thereby increasing a switching speed of the switching transistor. Further, a capacitance between the gate and the active layer of the driving transistor is decreased relative to that of the switching transistor, which delays a voltage change of the driving transistor, such that a subthreshold swing of the driving transistor is increased relative to that of the switching transistor, the incomplete display of gray levels of an OLED display device due to a too fast voltage change of the driving transistor is avoided, and the display effect of the gray levels of the OLED device is improved.

An embodiment of the present disclosure provides an OLED display device, which includes the OLED array substrate according to any one of the foregoing embodiments.

By including the OLED array substrate according to any one of the foregoing embodiments, the OLED display device has an increased response speed and an improved display effect.

The OLED display device provided by the present disclosure may be any product or component having a display function, such as an OLED panel, an OLED television, a display, a mobile phone, a navigator or the like.

It should be understood that, the above embodiments are only exemplary embodiments for the purpose of explaining the principle of the present disclosure, and the present disclosure is not limited thereto. For one of ordinary skill in the art, various improvements and modifications may be made without departing from the spirit and essence of the present disclosure. These improvements and modifications also fall within the protection scope of the present disclosure.

1. An OLED array substrate, comprising a switching transistor for controlling a pixel to display and a driving transistor for driving the pixel to display, wherein the switching transistor comprises an active layer, a gate, and a first insulation layer provided between the active layer and the gate, the driving transistor comprises an active layer, a gate, and a second insulation layer provided between the active layer and the gate of the driving transistor, and the first insulation layer has a dielectric constant greater than that of the second insulation layer.

2. The OLED array substrate according to claim 1, wherein the first insulation layer is made of silicon nitride, and the second insulation layer is made of silicon dioxide.

3. The OLED array substrate according to claim 2, wherein the first insulation layer has a thickness ranging from 50 nm to 150 nm, and the second insulation layer has a thickness ranging from 120 nm to 200 nm.

4. The OLED array substrate according to claim 1, wherein the first insulation layer comprises a bottom sub-layer and a top sub-layer which are stacked on each other, the bottom sub-layer is in contact with the active layer of the switching transistor, and the top sub- layer is in contact with the gate of the switching transistor; the bottom sub-layer is made of silicon dioxide, and the top sub-layer is made of silicon nitride; and
the second insulation layer is made of silicon dioxide.

5. The OLED array substrate according to claim 4, wherein the bottom sub-layer has a thickness ranging from 30 nm to 50 nm, and the top sub-layer has a thickness ranging from 50 nm to 150 nm; and
the second insulation layer has a thickness ranging from 120 nm to 200 nm.

6. The OLED array substrate according to claim 1, wherein each of the active layer of the switching transistor and the active layer of the driving transistor is made of low temperature poly-silicon.

7. The OLED array substrate according to claim 1, wherein both the switching transistor and the driving transistor are one of top-gate transistors and bottom-gate transistors.

8. An OLED display device, comprising the OLED array substrate according to claim 1.

9. A method for manufacturing an OLED array substrate, the OLED array substrate being the OLED array substrate according to claim 1, and the method comprising steps of forming the switching transistor and forming the driving transistor, wherein the step of forming the switching transistor comprises forming the first insulation layer between the active layer and the gate of the switching transistor, and the step of forming the driving transistor comprises forming the second insulation layer between the active layer and the gate of the driving transistor, such that the first insulation layer has a dielectric constant greater than that of the second insulation layer.

10. The method according to claim 9, wherein the active layer of the switching transistor and the active layer of the driving transistor are made of a same material by one process, and the gate of the switching transistor and the gate of the driving transistor are made of a same material by one process.

11. The OLED array substrate according to claim 2, wherein each of the active layer of the switching transistor and the active layer of the driving transistor is made of low temperature poly-silicon.

12. The OLED array substrate according to claim 3, wherein each of the active layer of the switching transistor and the active layer of the driving transistor is made of low temperature poly-silicon.

13. The OLED array substrate according to claim 4, wherein each of the active layer of the switching transistor and the active layer of the driving transistor is made of low temperature poly-silicon.

14. The OLED array substrate according to claim 5, wherein each of the active layer of the switching transistor and the active layer of the driving transistor is made of low temperature poly-silicon.

15. The OLED array substrate according to claim 2, wherein both the switching transistor and the driving transistor are one of top-gate transistors and bottom-gate transistors.

16. The OLED array substrate according to claim 3, wherein both the switching transistor and the driving transistor are one of top-gate transistors and bottom-gate transistors.

17. The OLED array substrate according to claim 4, wherein both the switching transistor and the driving transistor are one of top-gate transistors and bottom-gate transistors.

18. The OLED array substrate according to claim 5, wherein both the switching transistor and the driving transistor are one of top-gate transistors and bottom-gate transistors.

19. The OLED array substrate according to claim 6, wherein both the switching transistor and the driving transistor are one of top-gate transistors and bottom-gate transistors.

20. The OLED array substrate according to claim 11, wherein both the switching transistor and the driving transistor are one of top-gate transistors and bottom-gate transistors.
